(19) United States
(12) Patent Application Publication
(10) Pub. No.: US 2009/0186550 A1
(43) Pub. Date: Jul. 23, 2009

(54) METHODS, APPARATUS, AND ROLLERS FOR FORMING OPTOELECTRONIC DEVICES

(75) Inventors: Donald Franklin FOUST, Glenville, NY (US); Hak Fei POON, Downingtown, PA (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: GENERAL ELECTRIC COMPANY, Schenectady, NY (US)

(21) Appl. No.: 12/017,140

(22) Filed: Jan. 21, 2008

(51) Int. Cl. H01J 9/42

(52) U.S. Cl. 445/3; 445/63

(57) ABSTRACT

Apparatus and methods for forming optoelectronic devices such as an array of light emitting diodes or photovoltaic cells employ in one embodiment a roll-to-roll process in which a uniquely configured roller having a plurality of spaced-apart raised coating surfaces is aligned with a plurality of columns of first electrodes on a substrate for coating a plurality of spaced-apart strips of optoelectronic materials along the longitudinal direction of the substrate and on a plurality of spaced-apart columns of the first electrodes.

### CROSS-REFERENCE TO RELATED APPLICATION

This application is related to commonly owned, and co-filed U.S. patent application Ser. No. ______, entitled “Methods, Apparatus, and Rollers For Cross-Web Forming Of Optoelectronic Devices” by Poon et al. (Docket No. 219818), which is hereby incorporated herein by reference in its entirety.

### FIELD OF THE INVENTION

Embodiments of the present invention generally relate to optoelectronic devices. More particularly, embodiments of the present invention relate to methods, apparatus, and rollers for forming optoelectronic devices and patterned films for large area optoelectronic devices such as light emitting diodes and photovoltaic devices.

### BACKGROUND OF THE INVENTION

Organic electroluminescent devices (OLEDs) typically includes one or more light emitting layers disposed between two electrodes, e.g., a cathode and a light transmissive anode, formed on a light transmissive substrate. The light emitting layer emits light upon application of a voltage across the anode and cathode. Upon the application of a voltage from a voltage source, electrons are directly injected into the organic layer from the cathode, and holes are directly injected into the organic layer from the anode. The electrons and the holes travel through the organic layer until they recombine at a luminescent center. This recombination process results in the emission of a photon, i.e., light. Large area OLED devices typically combine many individual OLED devices on a single substrate or a combination of substrates with multiple individual OLED devices on each substrate. Applications for large area OLED devices include area lighting.

Electroluminescent layer patterning has been conventionally performed using stamping or laser ablation. In stamping, a pattern is imprinted upon the layer using mechanical force upon a patterned die or a stamping head, whereas in laser ablation, a patterned photomask covers the area to be patterned while the remaining area is selectively etched using a laser beam. Another approach includes inkjet printing.

A recent attempt for applying the patterned active electroluminescent layer is disclosed in U.S. Patent Application Publication No. 2005/0129977 by Poon et al., which includes a combination of a web coating using a roller having an elongated coating surface such as a micro gravure coating process and a solvent assisted wiping process for removing portions of the applied active electroluminescent web coated layer. U.S. Pat. No. 7,049,757 discloses an array of light devices connected in series.

Organic photovoltaic (OPV) devices may be fabricated using similar materials and concepts as the OLED devices. Organic photovoltaic (OPV) devices typically include at least two layers of organic semiconducting materials disposed between two conductors or electrodes. At least one layer of organic semiconducting material is an electron acceptor, and at least one layer of organic material is an electron donor. An electron acceptor is a material that is capable of accepting electrons from another adjacent material due to a higher electron affinity of the electron acceptor. An electron donor is a material that is capable of accepting holes from an adjacent material due to a lower ionization potential of the electron donor. The absorption of photons in an organic photoconductive material results in the creation of bound electron-hole pairs, which must be dissociated before charge collection can take place. The separated electrons and holes travel through their respective acceptor (semiconducting material) to be collected at opposite electrodes.

There is a need for further deposition and patterning techniques in the fabrication of organic electronic devices.

### SUMMARY OF THE INVENTION

The present invention, in a first aspect, is directed to a method for forming a plurality of optoelectronic devices. The method includes providing a substrate having a longitudinal web direction and a cross-web direction, and a plurality of first electrodes disposed on the substrate to define a plurality of longitudinally-extending columns of spaced-apart first electrodes along the longitudinal web direction and a plurality of rows of spaced-apart first electrodes along the cross-web direction. A first roller having a first plurality of spaced-apart channels defining a first plurality of spaced-apart coating surfaces is provided. The substrate and the plurality of spaced-apart longitudinally-extending columns of the first electrodes are aligned and passed relative to the first roller to deposit from the first plurality of spaced-apart coating surfaces a first plurality of spaced-apart longitudinally-extending coated strips of a first optoelectronic material onto the substrate and onto the plurality of rows of first electrodes. A second roller having a second plurality of spaced-apart channels defining a second plurality of spaced-apart coating surfaces is provided. The substrate, the plurality of spaced-apart longitudinally-extending columns of first electrodes, and the first plurality of spaced-apart longitudinally-extending coated strips of the first optoelectronic material are aligned and passed relative to the second roller to deposit from the second plurality of spaced-apart coating surfaces a second plurality of spaced-apart longitudinally-extending coated strips of a second optoelectronic material onto the first plurality of spaced-apart longitudinally-extending coated strips of a first optoelectronic material while the other portions of the plurality of columns of first electrodes remain uncoated with the second optoelectronic material. A plurality of spaced-apart second electrodes is provided electrically coupling uncoated portions of the first electrodes with the coated portions disposed on adjacent first electrodes to form a plurality of rows of optoelectronic devices connected in series along the cross-web direction.

The present invention, in a second aspect, is directed to a method for forming a plurality of optoelectronic devices. The method includes providing a substrate having a longitudinal web direction and a cross-web direction, and a plurality of first electrodes disposed on the substrate to define a plurality of columns of spaced-apart first electrodes along the longitudinal web direction and a plurality of rows of spaced-apart first electrodes along the cross-web direction. The substrate and the plurality of longitudinally-extending columns of the first electrodes are aligned and passed relative to a first roller means for depositing a first plurality of longitudinally-extending spaced-apart coated strips of a first optoelectronic material onto the substrate and onto portions of the plurality of columns of the first electrodes while other portions of the plurality of columns of first electrodes remain uncoated with first optoelectronic material. The substrate, the plurality of longitudinally-extending columns of the first electrodes, and the first plurality of longitudinally-extending coated strips of the first optoelectronic material are aligned and passed relative to a second roller means for depositing a second plurality of longitudinally-extending coated strips of a second optoelectronic material onto the first plurality of longitudinally-extending coated strips of a first optoelectronic material while the other portions of the plurality of columns of first electrodes remain uncoated with the second optoelectronic material. A plurality of spaced-apart second electrodes are provided electrically coupling uncoated portions of the first electrodes with the coated portions disposed on adjacent first electrodes to form a plurality of rows of optoelectronic devices connected in series along the cross-web direction.

The present invention, in a third aspect, is directed to an apparatus for use in forming a plurality of optoelectronic devices. The apparatus includes a first roller means having a plurality of spaced-apart raised coating surfaces for receiving a first optoelectronic material, and depositing a plurality of longitudinally-extending strips of the first optoelectronic material and first means for containing a first optoelectronic material and for receiving the spaced-apart raised coating surfaces of the first roller so that the spaced-apart coating surfaces of the first roller is positionable in the first optoelectronic material.

The present invention, in a fourth aspect, is directed to a roller for use in forming a plurality of optoelectronic devices. The roller includes an elongated means having a plurality of first spaced-apart raised coating surfaces for receiving an optoelectronic material and depositing a plurality of longitudinally-extending strips of the first optoelectronic material.

### BRIEF DESCRIPTION OF THE DRAWINGS

The subject matter which is regarded as the invention is particularly pointed out and distinctly claimed in the concluding portion of the specification. The invention, however, may best be understood by reference to the following detailed description of various embodiments and the accompanying drawings in which:

FIG. 1 is a top view of one embodiment of an array of optoelectronic devices fabricated in accordance with embodiments of the present invention;

FIG. 2 is a cross-sectional view of a number of the optoelectronic devices of FIG. 1;

FIG. 3 is a side elevational view of one embodiment of a roller having evenly sized and spaced-apart coating surfaces in accordance with the present invention for use in forming the array of optoelectronic devices of FIG. 1;

FIG. 4 is a simplified diagrammatic view of one embodiment of an apparatus in accordance with the present invention for depositing the optoelectronic materials used to form the optoelectronic devices of FIG. 1;

FIG. 5 is a top view of a portion of a substrate having a plurality of longitudinally-extending columns of spaced-apart first electrodes and a plurality of rows of spaced-apart first electrodes;

FIG. 6 is a top view of a portion of the substrate and a plurality of longitudinally-extending columns of spaced-apart first electrodes and a plurality of rows of spaced-apart first electrodes of FIG. 5 having a plurality of columns of a first optoelectronic material and a second optoelectronic material deposited thereon;

FIG. 7 is a top view of a portion of the substrate, the plurality of spaced-apart first electrodes, and the plurality of optoelectronic materials of FIG. 6, with a plurality of second electrodes disposed thereon;

FIG. 8 is a top view of a portion of the substrate, a plurality of spaced-apart first electrodes, and the plurality of columns of the first and second optoelectronic materials deposited thereon of FIG. 6 with portions of the columns of optoelectronic materials removed between adjacent rows of the first electrodes;

FIG. 9 is a simplified diagrammatic view of another embodiment of an apparatus in accordance with the present invention having a plurality of rollers for depositing the optoelectronic materials used to form the array of optoelectronic devices of FIG. 1;

FIG. 10 is side elevational view of the second roller of FIG. 9 and a plurality of reservoirs containing a plurality of different optoelectronic materials;

FIG. 11 is a side elevational of one embodiment of a set of rollers having a plurality of offset coating surfaces in accordance with the present invention for use in forming an array of optoelectronic devices of FIG. 1.

FIG. 12 is a side elevational view of another embodiment of a roller having unevenly sized and spaced-apart coating surfaces in accordance with the present invention for use in forming an array of optoelectronic devices; and

FIG. 13 is one embodiment of a flowchart of a method for forming the array of optoelectronic devices of FIG. 1.

### DETAILED DESCRIPTION OF THE INVENTION

As described in greater detail below, aspects of the present invention are generally directed to methods, apparatus, and rollers for forming optoelectronic devices such as an array of light emitting diodes or photovoltaic cells using a roll-to-roll process in which a uniquely configured roller having a plurality of coating surfaces is aligned with a plurality of columns of first electrodes on a substrate for coating a plurality of spaced-apart strips of an optoelectronic material along the longitudinal direction of the substrate.

Initially, with reference to FIG. 1, therein illustrated is an exemplary array 10 of optoelectronic devices 20 such as a plurality of light emitting diodes (OLEDs) supported on a substrate 12. The array may be configured for use as a large area lighting array. From the following description, it will be appreciated by those skilled in the art that other optoelectronic devices may be fabricated using the techniques in accordance with the present invention such as photovoltaic devices (OPVs). The array is patterned to provide a dense layer of discrete, electrically isolated patches or “elements.” By patterning one or more layers of each discrete device 20, shorting between the top and bottom electrodes, as described below, will only affect the elements that are shorted, rather than shorting the entire array. In one embodiment, the size of the elements may be about ½-inch by about ½-inch. From the present description, it will be appreciated that other sizes and shapes of elements may be suitably employed.

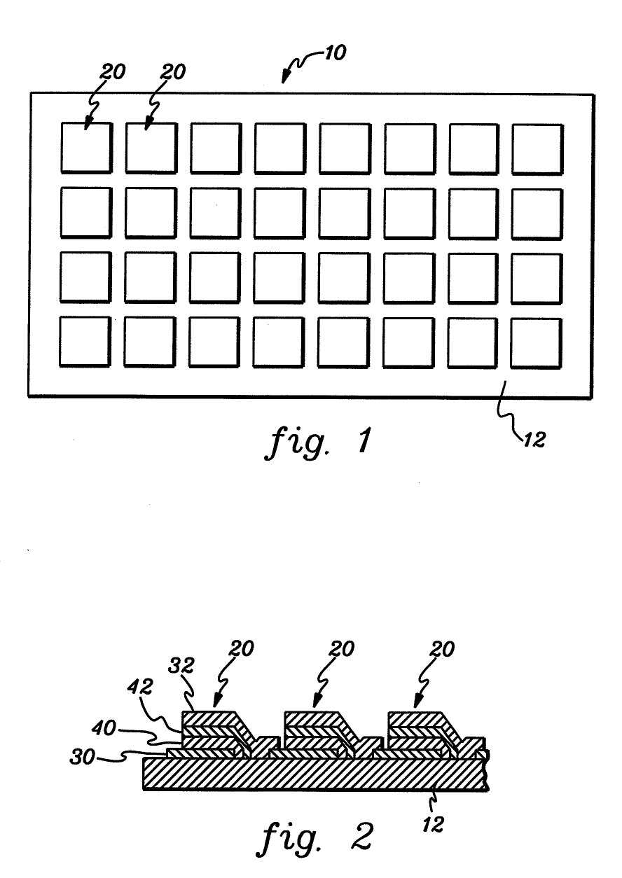

As shown in FIG. 2, the optoelectronic devices 20 may be coupled in series. For example, the plurality of first electrodes 30 may be disposed and patterned on substrate 12 to form isolated structures. A first optoelectronic material 40 may be disposed on the plurality of first electrodes 30, and a second optoelectronic material 42 may be disposed on the first optoelectronic material 40. A plurality of second electrodes 32 may be disposed and patterned to provide an electrically conductive path to the first electrode 30 of an adjacent optoelectronic device in a single row of the array. As will be appreciated, by providing series connections for each of the adjacent devices in a single row, a structure tolerant to electrical shorts (short-tolerant structure) is provided.

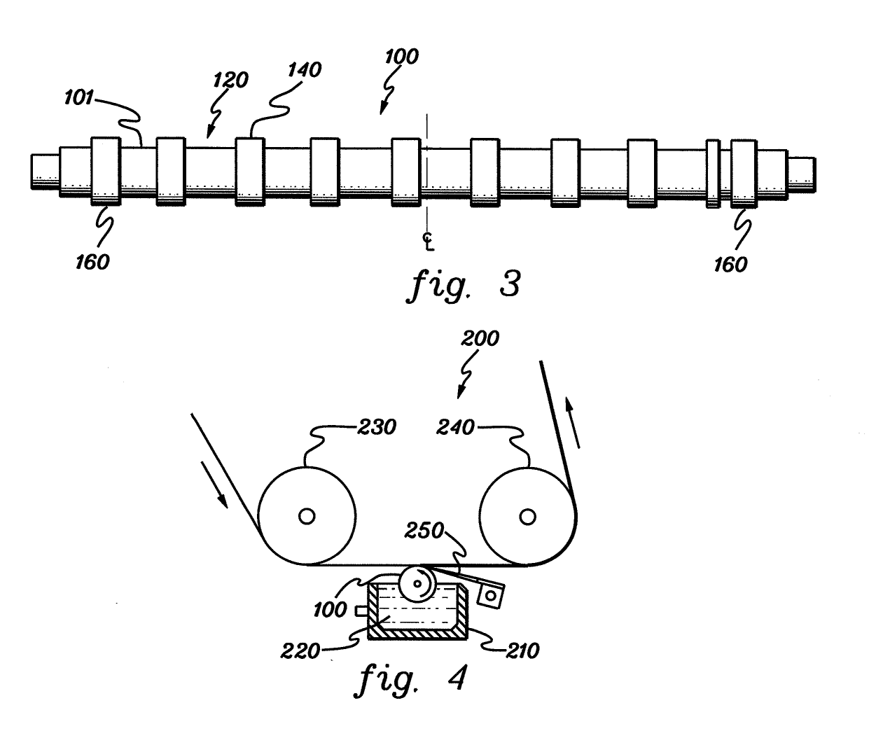

As shown in FIG. 3, one embodiment of a roller 100 may include an elongated member 101 having a plurality of spaced-apart circumferentially-extending recessed channels 120 defining a plurality of spaced-apart raised coating surfaces 140 for applying the layers of optoelectronic materials as described below. The coating surfaces may be an engraved surface engraved with patterns, cells or grooves which determine a finite volume of internal capacity, and may include an engraved roll (“gravure roll”). The geometry, number and spacing, depth or other features of the cells can be varied to produce a range of total volume to accomplish coating weight (thickness) control of the applied layers of optoelectronic materials. Roller 100 may be configured so that the spacing between adjacent coating surfaces is generally equal, and the spacing between adjacent channels is generally equal. The coating surfaces may extend about 0.06 inches above the bottom of the channels although other dimensions may be suitably employed. The width of the coating surfaces may be about 0.25 inch or smaller to about 0.5 inch or greater. The coating surface may include a plurality of grooves or lines disposed on an angle relative to the axis of the roller and may include, for example, about 200 grooves or lines per inch.

With reference to FIG. 4, one embodiment of an apparatus 200 for forming a plurality of optoelectronic devices may include roller 100 mounted on bearings 160 (FIG. 3) and rotated to be partially submerged in a reservoir 210 filled with a solution of liquid optoelectronic material 220 (a solid dissolved in a solvent) which is to be applied. Rollers 230 and 240 are configured to support the web of material to be processed over roller 100. As described in greater detail below, in accordance with embodiments of the present invention, the liquid optoelectronic material may comprise an active polymer material such as an light emitting polymer (LEP) or poly(3,4-ethylenedioxythiophene) (PEDOT) layer for forming an array of light emitting diodes.

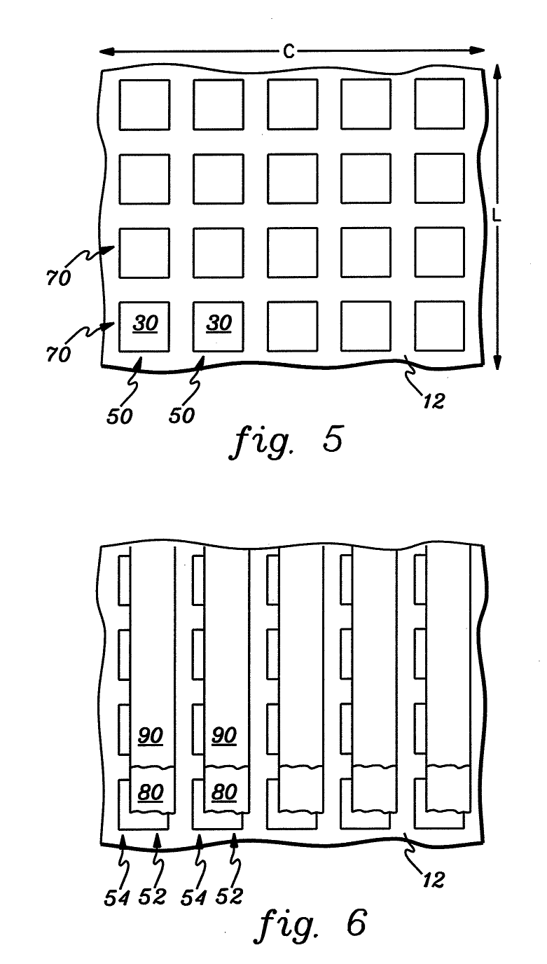

During fabrication, as initially shown in FIG. 5, one embodiment of a method for forming the plurality of optoelectronic devices 10, includes providing flexible substrate 12 having a longitudinal web direction L and a cross-web direction C having a plurality of first electrodes 30 disposed on the substrate to define a plurality of longitudinally-extending columns 50 of spaced-apart first electrodes along the longitudinal web direction and a plurality of rows 70 of spaced-apart first electrodes along the cross-web direction.

With reference to FIGS. 4-6, substrate 12 and the plurality of spaced-apart longitudinally-extending columns 50 of the first electrodes are aligned or registered with and passed relative to roller 100 to deposit or coat selectively from the first plurality of spaced-apart coating surfaces 140 (FIG. 3) of roller 100, as shown in FIG. 6, a first plurality of spaced-apart longitudinally-extending coated strips 80 of a first optoelectronic material from the reservoir onto substrate 12 and onto portions 52 of the plurality of columns 50 of first electrodes 30 while other portions 54 of the plurality of columns 50 of first electrodes 30 remain uncoated with the first optoelectronic material.

With reference again to FIG. 4, the substrate and plurality of first electrodes may be made to be spaced-apart from and not in direct physical contact with roller 100. Instead, the first optoelectronic material disposed on the plurality of coating surfaces of roller 100 may be made to contact the substrate and plurality of first electrodes. A flexible steel blade 250 may be positioned to scrape excess optoelectronic material from the coating surfaces of roller 100 as roller 100 rotates toward the contact point of the substrate. Desirably, roller 100 is reverse-wiped across a moving tensioned reel-to-reel surface of the substrate having the plurality of columns of first electrode thereon. Use of a reverse coating results in a shearing force imparted onto the optoelectronic material as it is applied resulting in a generally uniform thin coated layer. It will be appreciated that forward or reverse coating may be employed.

Once the optoelectronic material has dried, for example in a drying chamber or the application of heat, apparatus 200 may be employed to coat a second optoelectronic material. For example, the contents of reservoir 210 may be replaced with a second optoelectronic material. Roller 100 having the plurality of spaced-apart coating surfaces 140 may be dipped into the second optoelectronic material in the reservoir. The substrate, the plurality of spaced-apart longitudinally-extending columns of first electrodes, and the first plurality of spaced-apart longitudinally-extending coated strips of the first optoelectronic material are aligned or registered and passed relative to roller 100 to deposit from the plurality of spaced-apart coating surfaces, as shown in FIG. 6, a second plurality of spaced-apart longitudinally-extending coated strips 90 of a second optoelectronic material from a second reservoir onto the first plurality of spaced-apart longitudinally-extending coated strips 80 of a first optoelectronic material while the other portions 54 of the plurality of columns 50 of first electrodes remain uncoated with the second optoelectronic material. From the present description, it will be appreciated that the coating surfaces of the roller may be configured to produce other shaped longitudinally-extending coated strips compared to the longitudinally-extending coated strips shown in FIG. 6.

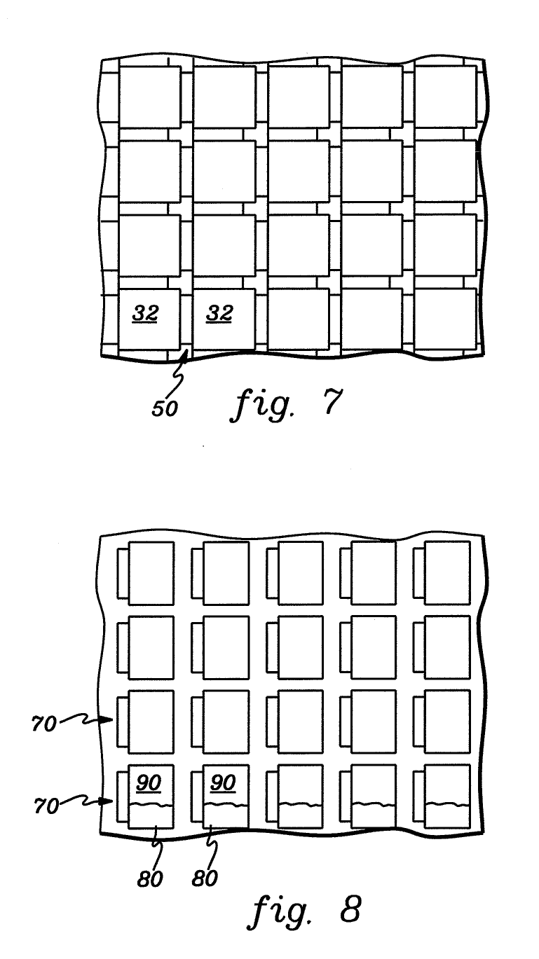

Thereafter, as shown in FIG. 7, a plurality of spaced-apart second electrodes 32 is disposed electrically coupling uncoated portions 54 of the first electrodes with the coated portions disposed on adjacent first electrodes to form a plurality of rows of optoelectronic devices connected in series along the cross-web direction. The spaced-apart second electrodes may be deposed using a masking and deposition process such as evaporation or sputtering, or other suitable processes. The array of optoelectronic devices may be cut to a suitable size from the web, and the plurality of rows of serially electrically connected optoelectronic devices may further be electrically connecting in parallel, for example along the edges of the array.

In an alternative embodiment, as shown in FIG. 8, the portions of the deposited spaced-apart longitudinally-extending coated strips 80 and 90 of the first optoelectronic material and the second optoelectronic material between adjacent rows 70 of the space-apart first electrodes as shown in FIG. 6, may be removed. This step may be desirable where the rows of elements are spaced closely to each other to inhibit current flow through the optoelectronic materials between adjacent rows. The second electrodes would then be similarly deposited as shown in FIG. 7. The removal of the portions of the deposited spaced-apart longitudinally-extending coated strips may include an etching process, wiping process, other suitable process. For example, suitable solvent assisted wiping (SAW) processes are disclosed in U.S. Patent Application Publication Nos. 2005/0129977 by Poon et al. and 2006/0202612 by Poon et al., the entire contents of which are incorporated herein by reference.

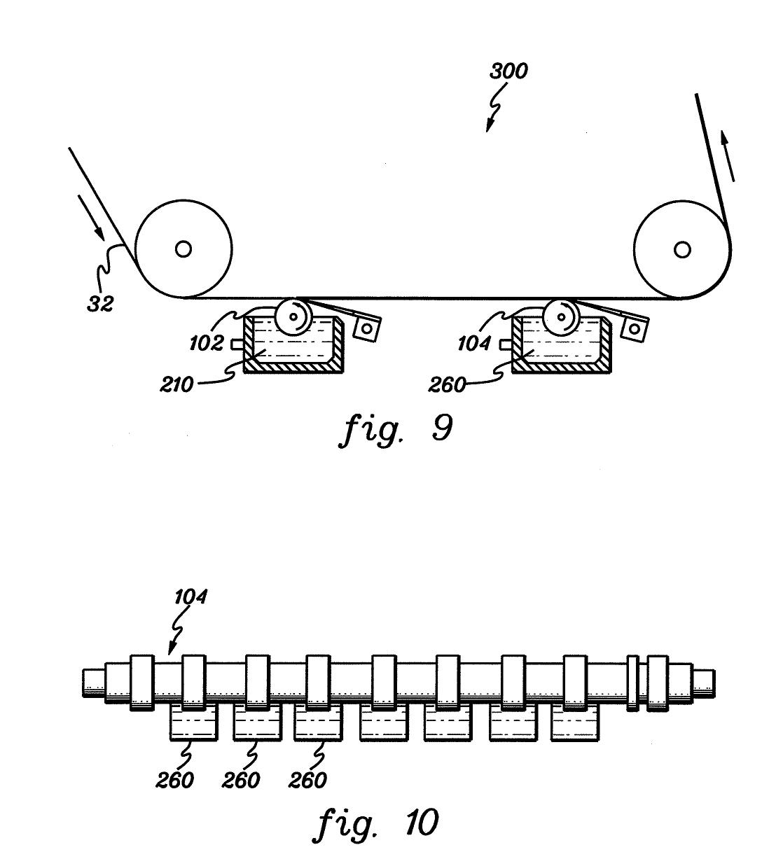

FIG. 9 illustrates a second embodiment of an apparatus 300 that employs a first roller 102 and a second roller 104 which may be essentially the same roller 100 shown in FIG. 3 having a plurality of spaced-apart circumferentially-extending channels defining a plurality of spaced-apart coating surfaces for applying the aligned layers of optoelectronic materials. The optoelectronic materials may tend to spread once applied to the substrate, the first electrode, or the first applied optical material. Since the different optoelectronic materials may spread differently, the spacing between the coating surfaces may be sized differently depending on the optoelectronic material being applied. For example, PDOT has shown a spreading (on an edge from the coating surface) of about 125 microns while LEP has shown a spreading of about 250 microns.

In addition, for forming a plurality of electroluminescent devices such as organic light emitting diodes, the second roller 104 may be employed to deposit the second plurality of longitudinally-extending coated strips comprising different second electroluminescent materials from a plurality of separate reservoirs 260, as best shown in FIG. 10, onto the first plurality of longitudinally-extending coated strips of the first optoelectronic material, and wherein the different second electroluminescent materials result in the plurality of electroluminescent devices operable to emit different colors of light. For example, different electroluminescent materials may be employed to produce an array of light emitting diodes having stripes of light emitting diodes of red, green, and blue. Desirably, a diffuser may be disposed adjacent to the array so that the red, green, and blue emitted colors are combined and generally emitted as white light from the diffuser. From the present description, it will be appreciated that other approaches using aspects of the apparatus and methods of the present invention may be employed to produce emissions of generally white light.

With reference again to FIG. 3, roller 100 may have a plurality of spaced-apart coating surfaces, which are offset relative to a centerline of the roller. This would allow the roller to be first used to apply a first coating of materials on every other column of the first electrodes. Then the roller can be flipped to coat uncoated columns of the first electrodes. Different materials may be used to produce an array of light emitting diodes operable to emit alternating stripes of different colors.

Further, for forming a plurality of electroluminescent devices such as organic light emitting diodes, a plurality of second rollers 106 and 108, as shown in FIG. 11, having a plurality of offset spaced-apart coating surfaces 107 and 109 to deposit the second plurality of longitudinally-extending coated strips comprising different second electroluminescent materials from a plurality of separate reservoirs onto the first plurality of longitudinally-extending coated strips. The different second electroluminescent materials may result in the plurality of electroluminescent devices operable to emit different colors of light.

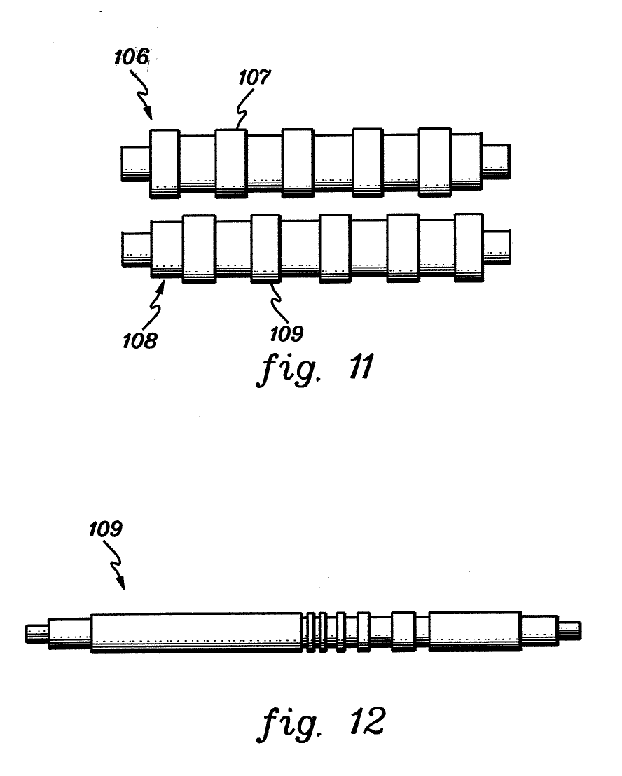

FIG. 12 illustrates a second embodiment of a roller 110 having a plurality of unequal channels and unequal coating surfaces. A resulting array of optoelectronic devices may have a plurality of different sized columns of optoelectronic devices.

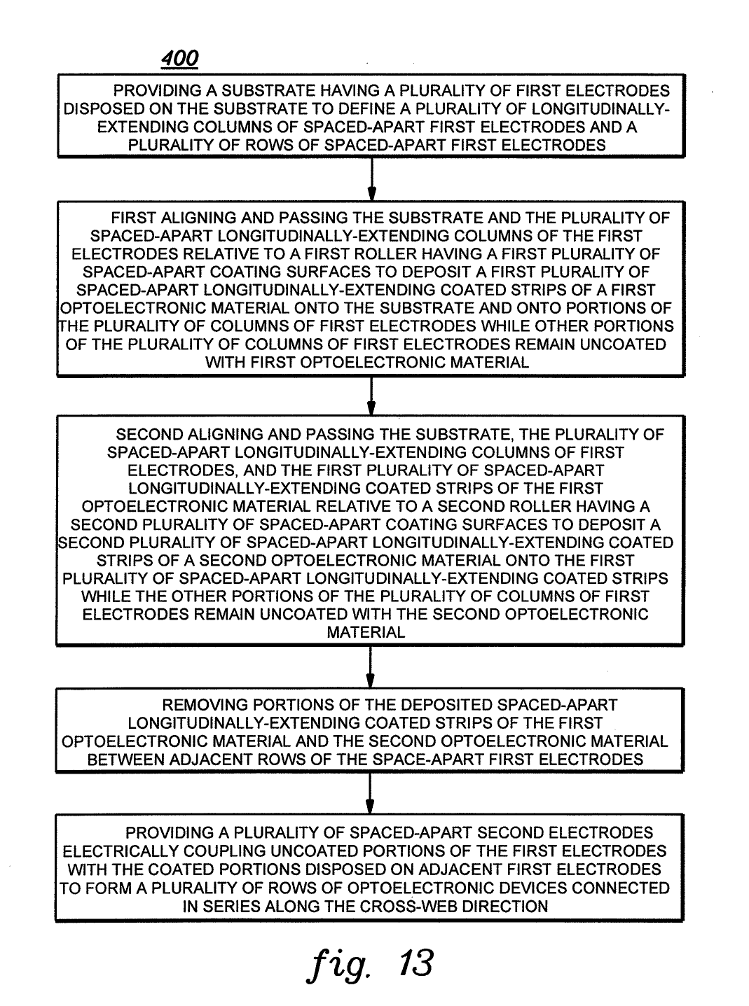

Referring now to FIG. 13, a flowchart illustrates a process 400 for manufacturing an array of organic electronic devices in accordance with embodiments of the present invention.

In the various embodiments of the present invention, the flexible substrate may comprise any suitable material, such as polyethylene terepthalate (PET), polycarbonate (e.g., LEXAN), polymer material (e.g., MYLAR), polyester, or metal foil, for example. In some embodiments, the substrate comprises any material having a high melting point, thereby allowing for high processing temperatures (e.g., >200 degrees C.). Further, the substrate may be advantageously transparent and has a high rate of transmission of visible light (e.g., >85% transmission). Further, the substrate may advantageously comprise a material having a high impact strength, flame retardancy and thermoformability, for example.

The substrate may have a thickness in the range of approximately 1-125 mils. As can be appreciated, a material having a thickness of less than 10 mils (0.010 inch) may generally be referred to as a “film” while a material having a thickness of greater than 10 mils (0.010 inch) may generally be referred to as a “sheet.” It should be understood that the substrate may comprise a film or a sheet. Accordingly, the use of either term herein is not meant to limit the thickness of the respective material, but rather, is provided for simplicity.

As previously described, the plurality of optoelectronic devices may be organic light emitting diodes (OLEDs), each of which may include a first electrode, active polymer optoelectronic layers, and a second electrode. The first electrode may be configured to form the anode of the OLED and may comprise a transparent conductive oxide (TCO), such as indium-tin-oxide (ITO), for example. The transparent ITO may be disposed on the flexible transparent substrate using roll-to-roll processing techniques. For instance, the first electrode may be disposed by sputtering techniques to achieve a thickness in the range of approximately 50-250 nanometers, for example. The first electrode preferably has a light transmission ratio of at least 0.8. The second electrode is configured to form the cathode and may comprise an aluminum film with a cathode activator NaF, for instance. Alternatively, the second electrode may comprise calcium, magnesium or silver, for example. As with the first electrode, the second electrode may be disposed using sputtering techniques to achieve a thickness in the range of 50-250 nanometers, for example. For bottom-emitting OLED devices, the second electrode is advantageously reflective to reflect impinging light toward the front of the device where it can be coupled to the ambient environment. As will be appreciated, when a voltage potential is produced across the first electrode and the second electrode, light is emitted from the active polymer layers. Alternatively, both electrodes may be transparent, to enable a transparent light-emitting device, or the bottom electrode may be reflective, and the top electrode transparent, in the case of a top-emitting OLED.

As previously described, a number of active polymer layers may be disposed between the first electrode and the second electrode. As can be appreciated, for an OLED device, the active polymer layers may comprise several layers of organic light-emitting polymers, such as a polyphenylene vinylene or a polyfluorene, typically from a xylene solution. The number of layers and the type of organic polymers disposed will vary depending on the application, as can be appreciated by those skilled in the art. In one exemplary embodiment of an OLED device, one active polymer layer may comprise a light emitting polymer (LEP) such as polyfluorene, and the other active polymer layer may comprise a hole transport layer such as poly(3,4)-ethylendioxythiophene/polystyrene sulfonate (PEDOT/PSS). As will be appreciated, other light emitting polymers and hole transport or electron transport layers may be employed. Further, additional active polymer layers may be employed in the OLED device.

If the optoelectronic device is, for example, an organic photovoltaic (OPV) device, the types of organic materials used for the active polymer layers may be different from those described above with reference to the OLED devices. An organic PV device comprises one or more layers that enhance the transport of charges to the electrodes. For example, in an OPV device, the active polymer layers may include an electron donor material and an electron acceptor material. The electron donor layer may comprise metal-free phthalocyanine; phthalocyanine pigments containing copper, zinc, nickel, platinum, magnesium, lead, iron, aluminum, indium, titanium, scandium, yttrium, cerium, praseodymium, lanthanum, neodymium, samarium, europium, gadolinium, terbium, dysprosium, holmium, erbium, thulium, ytterbium, and lutetium; quinacridone pigment; indigo and thioindigo pigments; merocyanine compounds; cyanine compounds; squarylium compounds; hydrazone; pyrazoline; triphenylmethane; triphenylamine; conjugated electroconductive polymers, such as polypyrrole, polyaniline, polythiophene, polyphenylene, poly(phenylene vinylene), poly(thienylene vinylene), poly(isothianaphthalene); and poly(silane), for instance. Further, the electron donor material may also include a hole transport material, such as triaryldiamine, tetraphenyldiamine, aromatic tertiary amines, hydrazone derivatives, carbazole derivatives, triazole derivatives, imidazole derivatives, oxadiazole derivatives having an amino group, and polythiophene, for instance.

The electron acceptor material in an OPV device may include perylene tetracarboxidiimide, perylene tetracarboxidiimidazole, anthtraquinone acridone pigment, polycyclic quinone, naphthalene tetracarboxidiimidazole, CN- and CF3-substituted poly(phenylene vinylene), and Buckminsterfullerene, for instance. Further, the electron acceptor material may also include an electron transport material, such as metal organic complexes of 8-hydroxyquinoline; stilbene derivatives; anthracene derivatives; perylene derivatives; metal thioxinoid compounds; oxadiazole derivatives and metal chelates; pyridine derivatives; pyrimidine derivatives; quinoline derivatives; quinoxaline derivatives; diphenylquinone derivatives; nitro-substituted fluorine derivatives; and triazines, for example.

As noted above in connection with the forming of the array of optoelectronic devices, the coated layers of the optoelectronic material are removed between adjacent rows of the optoelectronic devices. In accordance with embodiments of the present invention, a solvent assisted wiping (SAW) technique may be implemented to pattern the columns of coated layers of the optoelectronic materials. As will be appreciated, SAW techniques facilitate the removal of material over a selected area by solvating a portion of the material, such as a portion of the columns of coated layers of the optoelectronic materials by at least one of water, methanol, ethanol, isopropanol, acetone, toluene, xylene, or combinations thereof. The surface of the solvated portion of the layers is then wiped by a wiping head to remove a portion of one or both of the layers, thereby patterning the layers. It will be appreciated that in certain embodiments of the present invention, one of the active polymer layers is disposed and patterned before the other active polymer layer is disposed and patterned. Alternatively, the active polymer layers may be disposed and subsequently patterned simultaneously. In one embodiment of the invention, the solvating species are selected for removing a single layer with each wiping action without damaging underlying layers. In this exemplary embodiment, one active polymer layer may be disposed and then patterned. Next, the other layer may be disposed and then patterned. The solvent used to pattern each layer will be different depending on the material of the layer being patterned. For example, an OLEP layer in a two-layer structure can be patterned using xylene as a solvent without damaging a PEDOT layer underneath.

In another embodiment, the solvating species are selected to facilitate removal of multiple active polymer layers with each wiping. That is, both active polymer layers may be disposed and then both active polymer layers may be patterned simultaneously. In typical instances, one active polymer layer comprises a conductive polymer coating, such as PEDOT, which is very polar and dissolves only in hydrogen-bonding solvents like water. The active polymer layer may comprise an LEP material that is non-polar, which dissolves only in non-polar solvents such as toluene or xylene. In order to remove multiple polymer coatings having extremely divergent solubility characteristics in a single wipe, suitable solvents for each polymer are dispersed in a third solvent to produce a homogeneous solution. The third, or dispersing, solvent is selected from a number of solvents, such as, but not limited to, alcohols (such as isopropanol, ethanol, methanol, and the like), ketones (such as acetone, methyl ethyl ketone, and the like), acetates, ethers, methylene chloride, or any solvent having intermediate solubility parameters. In this embodiment, two active polymer layers can also be removed in one step with a solvent system containing water and xylene. In this particular embodiment, isopropanol is used to facilitate mixing of water and xylene to yield a homogeneous solution.

The wiping head may generally comprise at least one of a sponge, elastomer, thermoplastic, thermoset, fiber mat, porous material, polyurethane rubber, synthetic rubber, natural rubber, silicones, polydimethylsiloxane (PDMS), textured materials, and combinations thereof. Further, the wiping head may have any desirable profile to achieve the desired patterning of the underlying layer.

Embodiments of the rollers of the present invention may be solid and formed form an integral, monolithic, or one-piece construction. Further, from the present description, the optoelectronic materials may be polymers, as well as small molecules, dendrimers, etc.

Thus, while various embodiments of the present invention have been illustrated and described, it will be appreciated to those skilled in the art that many changes and modifications may be made thereunto without departing from the spirit and scope of the invention.

1. A method for forming a plurality of optoelectronic devices, the method comprising:
providing a substrate having a longitudinal web direction and a cross-web direction, and a plurality of first electrodes disposed on the substrate to define a plurality of longitudinally-extending columns of spaced-apart first electrodes along the longitudinal web direction and a plurality of rows of spaced-apart first electrodes along the cross-web direction;
providing a first roller having a first plurality of spaced-apart channels defining a first plurality of spaced-apart coating surfaces;
first aligning and passing the substrate and the plurality of spaced-apart longitudinally-extending columns of the first electrodes relative to the first roller to deposit from the first plurality of spaced-apart coating surfaces a first plurality of spaced-apart longitudinally-extending coated strips of a first optoelectronic material onto the substrate and onto portions of the plurality of columns of first electrodes while other portions of the plurality of columns of first electrodes remain uncoated with first optoelectronic material;
providing a second roller having a second plurality of spaced-apart channels defining a second plurality of spaced-apart coating surfaces;
second aligning and passing the substrate, the plurality of spaced-apart longitudinally-extending columns of first electrodes, and the first plurality of spaced-apart longitudinally-extending coated strips of the first optoelectronic material relative to the second roller to deposit from the second plurality of spaced-apart coating surfaces a second plurality of spaced-apart longitudinally-extending coated strips of a second optoelectronic material onto the first plurality of spaced-apart longitudinally-extending coated strips of a first optoelectronic material while the other portions of the plurality of columns of first electrodes remain uncoated with the second optoelectronic material; and
providing a plurality of spaced-apart second electrodes electrically coupling uncoated portions of the first electrodes with the coated portions disposed on adjacent first electrodes to form a plurality of rows of optoelectronic devices connected in series along the cross-web direction.

2. The method of claim 1 wherein at least one of the first optoelectronic material and the second optoelectronic material comprises an electroluminescent material, and the plurality of optoelectronic devices comprise a plurality of electroluminescent devices.

3. The method of claim 2 wherein the second aligning and passing comprises aligning and passing the substrate, the plurality of longitudinally-extending columns of first electrodes, and the first plurality of longitudinally-extending coated strips relative to the second roller to deposit the second plurality of longitudinally-extending coated strips comprising different second electroluminescent materials from a plurality of reservoirs onto the first plurality of longitudinally-extending coated strips, and wherein the different second electroluminescent materials result in the plurality of electroluminescent devices operable to emit different colors of light.

4. The method of claim 2 wherein the second aligning and passing comprises aligning and passing the substrate, the plurality of longitudinally-extending columns of first electrodes, and the first plurality of longitudinally-extending coated strips relative to the second roller comprising a plurality of second rollers having a plurality of offset spaced-apart coating surfaces to deposit the second plurality of longitudinally-extending coated strips comprising different second electroluminescent materials from a plurality of reservoirs onto the first plurality of longitudinally-extending coated strips, and wherein the different second electroluminescent materials result in the plurality of electroluminescent devices operable to emit different colors of light.

5. The method of claim 1 further comprising removing portions of the deposited spaced-apart longitudinally-extending coated strips of the first optoelectronic material and the second optoelectronic material between adjacent rows of the space-apart first electrodes.

6. The method of claim 1 wherein the plurality of first electrodes define a uniform grid of electrodes.

7. The method of claim 1 wherein the providing the second roller comprises using the first roller and wherein the first plurality of spaced-apart coating surfaces comprises the second plurality of spaced-apart coating surfaces.

8. The method of claim 1 wherein the plurality of spaced-apart coating surfaces comprise at least one of a plurality of cells and grooves.

9. The method of claim 1 wherein the first roller and the second roller comprise a spacing between adjacent coating surfaces being generally equal, and a spacing between adjacent channels being generally equal.

10. The method of claim 1 wherein the first roller and the second roller comprise at least one of the spacing between adjacent coating surfaces being generally unequal, and the spacing between adjacent channels being generally unequal.

11. The method of claim 1 wherein the first optoelectronic material comprises a first light-absorbing material, the second optoelectronic material comprises a second light-absorbing material, and the plurality of optoelectronic devices comprises a plurality of photovoltaic devices.

12. The method of claim 1 further comprising electrically connecting in parallel the plurality of rows of serially electrically connected optoelectronic devices.

13. A method for forming a plurality of optoelectronic devices, the method comprising:
providing a substrate having a longitudinal web direction and a cross-web direction, and a plurality of first electrodes disposed on the substrate to define a plurality of columns of spaced-apart first electrodes along the longitudinal web direction and a plurality of rows of spaced-apart first electrodes along the cross-web direction;
first aligning and passing the substrate and the plurality of longitudinally-extending columns of the first electrodes relative to a first roller means for depositing a first plurality of longitudinally-extending spaced-apart coated strips of a first optoelectronic material onto the substrate and onto portions of the plurality of columns of the first electrodes while other portions of the plurality of columns of first electrodes remain uncoated with the first optoelectronic material;
second aligning and passing the substrate, the plurality of longitudinally-extending columns of the first electrodes, and the first plurality of longitudinally-extending coated strips of the first optoelectronic material relative to a second roller means for depositing a second plurality of longitudinally-extending coated strips of a second optoelectronic material onto the first plurality of longitudinally-extending coated strips of a first optoelectronic material while the other portions of the plurality of columns of first electrodes remain uncoated with the second optoelectronic material; and
providing a plurality of spaced-apart second electrodes electrically coupling uncoated portions of the first electrodes with the coated portions disposed on adjacent first electrodes to form a plurality of rows of optoelectronic devices connected in series along the cross-web direction.

14. The method of claim 13 wherein the second aligning and passing comprises aligning and passing the substrate, the plurality of longitudinally-extending columns of first electrodes, and the first plurality of longitudinally-extending strips relative to the second roller means to deposit the second plurality of longitudinally-extending coated strips comprising different second optoelectronic materials from a plurality of reservoirs onto the first plurality of longitudinally-extending coated strips, and wherein the different second optoelectronic materials result in the plurality of electroluminescent devices operable to emit different colors of light.

15. The method of claim 13 wherein the second aligning and passing comprises aligning and passing the substrate, the plurality of longitudinally-extending columns of first electrodes, and the first plurality of longitudinally-extending coated strips relative to the second roller comprising a plurality of second roller means to deposit the second plurality of longitudinally-extending strips comprising different second optoelectronic materials from a plurality of reservoirs onto the first plurality of longitudinally-extending coating strips, and wherein the different second optoelectronic materials result in the plurality of electroluminescent devices operable to emit different colors of light.

16. The method of claim 13 further comprising removing portions of the deposited longitudinally-extending strips of the first optoelectronic material and the second optoelectronic material between adjacent rows of the space-apart first electrodes.

17. The method of claim 13 wherein the plurality of first electrodes define a uniform grid of electrodes.

18. The method of claim 13 wherein the providing the second roller means comprises using the first roller means.

19. The method of claim 13 wherein the first and second roller means comprise a plurality of spaced-apart coating surfaces comprising at least one of a plurality of cells and grooves.

20. The method of claim 13 wherein a spacing between adjacent longitudinally-extending spaced-apart coated strips being generally equal, and a longitudinal width of the longitudinally-extending spaced-part coated strips being generally equal.

21. The method of claim 13 wherein at least one of the spacing between adjacent longitudinally-extending spaced-part coated strips being generally unequal, and the and a longitudinal width of the longitudinally-extending spaced-part coated strips being generally unequal.

22. The method of claim 13 further comprising electrically connecting in parallel the plurality of rows of serially electrically connected optoelectronic devices.

23. An apparatus for use in forming a plurality of optoelectronic devices, the apparatus comprising:
a first roller means having a plurality of spaced-apart raised coating surfaces for receiving a first optoelectronic material and depositing a plurality of longitudinally-extending strips of the first optoelectronic material; and
first means for containing a first optoelectronic material and for receiving said spaced-apart raised coating surfaces of said first roller so that said spaced-apart coating surfaces of said first roller is positionable in the first optoelectronic material.

24. The apparatus of claim 23 wherein said first means for containing and receiving comprises means for containing the first optoelectronic material comprising a first electroluminescent material and for receiving said spaced-apart raised coating surfaces of said first roller means so that said spaced-apart raised coating surfaces of said first roller means is positionable in the first electroluminescent material.

25. The apparatus of claim 23 wherein said means for containing and receiving comprises means for containing a plurality of different first electroluminescent materials, and for receiving said spaced-apart raised coating surfaces of said first roller means in the plurality of different first electroluminescent materials.

26. The apparatus of claim 23 wherein said first roller means comprises a spacing between adjacent raised coating surfaces being generally equal, and a width of said raised coating surfaces being generally equal.

27. The apparatus of claim 23 wherein said first roller means comprises at least one of a spacing between adjacent coating surfaces being generally unequal, and width of said raised coating surfaces being generally unequal.

28. The apparatus of claim 23 further comprising:
a second roller means having a plurality of spaced-apart raised coating surfaces for receiving a second optoelectronic material and depositing a plurality of longitudinally-extending strips of the second optoelectronic material, said plurality of spaced-apart raised coating surfaces of said second roller means being aligned with said plurality of spaced-apart coating surfaces of said first roller means; and
second means for containing a second optoelectronic material and for receiving said spaced-apart raised coating surfaces of said second roller means so that said spaced-apart coating surfaces of said second roller means is positionable in the second optoelectronic material.

29. The apparatus of claim 28 wherein said second means for containing and receiving comprises means for containing the second optoelectronic material comprising a second electroluminescent material and for receiving said spaced-apart material coating surfaces of said second roller means so that said spaced-apart coating surfaces of said second roller means is positionable in the second electroluminescent material.

30. The apparatus of claim 29 wherein said second means for containing and receiving comprises means for containing a plurality of different second electroluminescent materials, and for receiving said spaced-apart raised coating surfaces of said second roller means positionable in the plurality of different second electroluminescent materials.

31. The apparatus of claim 23 further comprising:
a plurality of second roller means having a plurality of offset spaced-apart raised coating surfaces for receiving a plurality of different second optoelectronic materials and for deposing a plurality of longitudinally-extending coated strips of the plurality of different second optoelectronic materials, said plurality of spaced-apart offset raised coating surfaces of said plurality of second roller means being aligned with said plurality of spaced-apart raised coating surfaces of said first roller means; and
means for containing a plurality of different second optoelectronic materials, and for receiving said spaced-apart offset raised coating surfaces positionable in the plurality of the second optoelectronic materials.

32. A roller for use in forming a plurality of optoelectronic devices, the roller comprising:
an elongated means having a plurality of first spaced-apart raised coating surfaces for receiving an optoelectronic material and depositing a plurality of longitudinally-extending coated strips of the first optoelectronic material.

33. The roller of claim 32 wherein said first roller means comprises a spacing between adjacent raised coating surfaces being generally equal, and a width of said plurality of raised coating surfaces being generally equal.

34. The roller of claim 32 wherein said first roller means comprises at least one of a spacing between adjacent raised coating surfaces being generally unequal, and width of said plurality of raised coating surfaces being generally unequal.

35. The roller of claim 32 wherein said plurality of spaced-apart raised coating surfaces comprise at least one of a plurality of cells and grooves.
